(19) United States
(12) Patent Application Publication
(10) Pub. No.: US 2025/0338620 A1
(43) Pub. Date: Oct. 30, 2025

(54) DISPLAY PANEL AND METHOD FOR MANUFACTURING THE SAME, AND TILED SCREEN DEVICE

(71) Applicant: Chengdu Vistar Optoelectronics Co., Ltd., Chengdu (CN)

(72) Inventors: Weihan LI, Chengdu (CN); Wei CHAO, Chengdu (CN); Xuan CAO, Chengdu (CN); Bo LI, Chengdu (CN); Yi CAI, Chengdu (CN)

(73) Assignee: Chengdu Vistar Optoelectronics Co., Ltd., Chengdu (CN)

(21) Appl. No.: 19/261,225

(22) Filed: Jul. 7, 2025

Related U.S. Application Data
(63) Continuation of application No. PCT/CN2024/073325, filed on Jan. 19, 2024.

(30) Foreign Application Priority Data
Feb. 23, 2023 (CN) 202310159191.5

(51) Int. Cl. H10D 86/40; H10D 86/01; H10D 86/60

(52) U.S. Cl. CPC H10D 86/441; H10D 86/0221; H10D 86/60

(57) ABSTRACT

A display panel and a method for manufacturing the same, and a tiled screen device. The display panel includes an array substrate, comprising a first surface, a second surface, and a first side surface connecting the first surface and the second surface, the first surface and the second surface being opposite to each other; a first pad, located on the first surface; a second pad, located on the second surface; a connecting trace, connecting the first pad and the second pad, the connecting trace is at least partially located on the first side surface; and a side boundary definition layer, located on an edge of the array substrate and located on a side of the connecting trace away from the array substrate. The display panel, the method for manufacturing the same, and the tiled screen device facilitate achieving narrow bezel.

### CROSS-REFERENCE TO RELATED APPLICATIONS

The present application is a continuation of International Application No. PCT/CN2024/073325 filed on Jan. 19, 2024, which claims the priority to Chinese Patent Application No. 202310159191.5 filed on Feb. 23, 2023, and titled “DISPLAY PANEL AND METHOD FOR MANUFACTURING THE SAME, AND TILED SCREEN DEVICE”, both of which are incorporated herein by reference in their entireties.

### TECHNICAL FIELD

The present application relates to the technical field of display, and in particular to a display panel and a method for manufacturing the same, and a tiled screen device.

### BACKGROUND

In recent years, narrow-bezel display panels have been increasingly used in various display devices to maximize the screen size. The concept and application of tiling multiple display panels are gradually emerging to achieve large-size display devices.

### SUMMARY

In a first aspect, embodiments of the present application provide a display panel. The display panel comprises: an array substrate, comprising a first surface, a second surface, and a first side surface connecting the first surface and the second surface, the first surface and the second surface being opposite to each other; a first pad located on the first surface; a second pad located on the second surface; a connecting trace connecting the first pad and the second pad, wherein the connecting trace is at least partially located on the first side surface; and a side boundary definition layer located on an edge of the array substrate and located on a side of the connecting trace away from the array substrate.

In a possible embodiment of the first aspect, a side surface of a terminal portion of the connecting trace comprises a second side surface, a side surface of a terminal portion of the side boundary definition layer comprises a third side surface, the second side surface and the third side surface are adjacent to each other and are opposite to the first side surface, and a maximum distance between the second side surface and the first side surface is less than or equal to a minimum distance between the third side surface and the first side surface.

In a possible embodiment of the first aspect, the display panel further comprises: a first conductive layer, located on the first surface, and a first terminal portion of the connecting trace is connected to the first pad via the first conductive layer; and/or a second conductive layer, located on the second surface, and a second terminal portion of the connecting trace is connected to the second pad via the second conductive layer.

Preferably, a side surface of a terminal portion of the side boundary definition layer comprises a third side surface, a side surface of a terminal portion of the first conductive layer comprises a fourth side surface, a side surface of a terminal portion of the second conductive layer comprises a fifth side surface, the third side surface and the fourth side surface are adjacent to each other and are opposite to the first side surface, and the third side surface and the fifth side surface are adjacent to each other and are opposite to the first side surface.

Preferably, a maximum distance between the fourth side surface and the first side surface is less than or equal to a minimum distance between the third side surface and the first side surface, and/or, a maximum distance between the fifth side surface and the first side surface is less than or equal to a minimum distance between the third side surface and the first side surface.

In a possible embodiment of the first aspect, the connecting trace is etchable by a chemical solution with a first acidity, and the first conductive layer and/or the second conductive layer is etchable by a chemical solution with a second acidity.

Preferably, a material of the first conductive layer and/or the second conductive layer comprises indium tin oxide, and/or, a material of the connecting trace comprises titanium copper. Preferably, the second acidity is less than the first acidity.

In a possible embodiment of the first aspect, the display panel further comprises: an encapsulation layer, located on an edge of the array substrate and covering the side boundary definition layer and the connecting traces.

Based on the same inventive concept, in a second aspect, embodiments of the present application provide a method for manufacturing a display panel, comprising: providing an array substrate, wherein the array substrate comprises a first surface, a second surface, and a first side surface connected to the first surface and the second surface, the first surface and the second surface are opposite to each other, the first surface is provided with a first pad, and the second surface is provided with a second pad; forming a metal connecting layer on the first surface, the second surface, and the first side surface, the metal connecting layer connecting the first pad and the second pad; patterning the metal connecting layer on an edge and the first side surface of the array substrate to form a connecting trace for connecting the first pad and the second pad; forming a side boundary definition layer on the edge of the array substrate and on a side of the connecting trace away from the array substrate; and removing part of the metal connecting layer exposed beyond the side boundary definition layer by taking an edge of the side boundary definition layer as a boundary.

In a possible embodiment of the second aspect, before the step of forming a metal connecting layer on the first surface, the second surface, and the first side surface, the method further comprises: forming a first sacrificial layer on the first surface; and correspondingly, after the step of removing portions of the metal connecting layer exposed beyond the side boundary definition layer, the method further comprises: removing part of the first sacrificial layer exposed beyond the side boundary definition layer by taking the edge of the side boundary definition layer as the boundary to form a first conductive layer, such that a first terminal portion of the connecting trace is connected to the first pad via the first conductive layer; and/or forming a second sacrificial layer on the second surface; correspondingly, after the step of removing portions of the metal connecting layer exposed beyond the side boundary definition layer, the method further comprises: removing part of the second sacrificial layer exposed beyond the side boundary definition layer by taking the edge of the side boundary definition layer as the boundary to form a second conductive layer, such that a second terminal portion of the connecting trace is connected to the second pad via the second conductive layer.

In a possible embodiment of the second aspect, the step of removing portions of the metal connecting layer exposed beyond the side boundary definition layer comprises: removing portions of the metal connecting layer exposed beyond the side boundary definition layer by wet etching and using a chemical solution with a first acidity; and the step of removing part of the first sacrificial layer exposed beyond the side boundary definition layer comprises: removing part of the first sacrificial layer exposed beyond the side boundary definition layer by wet etching and using a chemical solution with a second acidity; and/or the step of removing part of the second sacrificial layer exposed beyond the side boundary definition layer comprises: removing part of the second sacrificial layer exposed beyond the side boundary definition layer by wet etching and using a chemical solution with a second acidity. Preferably, the second acidity is less than the first acidity.

In a possible embodiment of the second aspect, after the step of removing portions of the metal connecting layer exposed beyond the side boundary definition layer, the method further comprises forming an encapsulation layer on the edge of the array substrate for covering the side boundary definition layer and the connecting traces.

Based on the same inventive concept, embodiments of the present application provide a tiled screen device comprising a display panel according to any one of the embodiments of the first aspect.

### BRIEF DESCRIPTION OF THE DRAWINGS

Other features, objects, and advantages of the present application will become more apparent from the following detailed description of non-limiting embodiments with reference to the accompanying drawings, in which same or similar reference numerals indicate same or similar features. The drawings are not drawn according to actual scale.

FIG. 1A shows a schematic structural view of a process for manufacturing a display panel in the related art;

FIG. 1B shows another schematic structural view of a process for manufacturing a display panel in the related art;

FIG. 2A shows a structural top view of a laser cutting error in a process for manufacturing a display panel in the related art;

FIG. 2B shows a structural top view after a protective layer is removed in a process for manufacturing a display panel in the related art;

FIG. 3 shows a structural side view of a display panel provided in embodiments of the present application;

FIG. 4 shows another structural side view of a display panel provided in embodiments of the present application;

FIG. 5 shows still another structural side view of a display panel provided in embodiments of the present application;

FIG. 6 shows a flow chart of a process for manufacturing a display panel provided in embodiments of the present application;

FIGS. 7A to 7E show schematic views of a process for manufacturing a display panel provided in embodiments of the present application;

FIG. 8 shows a flow chart of another process for manufacturing a display panel provided in embodiments of the present application;

FIGS. 9A to 9E show schematic views of another process for manufacturing a display panel provided in embodiments of the present application; and

FIG. 10 shows a flow chart of still another process for manufacturing a display panel provided in embodiments of the present application.

### DETAILED DESCRIPTION

Features and exemplary embodiments of various aspects of the present application will be described in detail below. In order to make the objects, technical solutions and advantages of the present application more clear, the present application will be further described in detail below with reference to the drawings and specific embodiments. It should be understood that, the specific embodiments described herein are only intended to explain the present application, but not to limit the present application. For those of ordinary skilled in the art, the present application may be implemented without some of those specific details. The following description of the embodiments is only for providing a better understanding of the present application by showing examples.

It should be noted that, relational terms such as first, second, and the like are used herein merely for distinguishing one entity or operation from another without necessarily requiring or implying any such actual relationship or order between such entities or operations. Moreover, the terms “include”, “comprise”, or any other variation thereof, are intended to cover a non-exclusive inclusion, such that a (n) process, method, article or device that includes a series of elements not only includes those elements but also includes other elements not explicitly listed or also includes elements inherent to such process, method, article or device. An element preceded by “include . . . ” does not, without more constraints, preclude the existence of additional identical elements in the process, method, article or device that includes the element.

It should be understood that, term “and/or” used herein refers to only an association relationship for describing associated objects, which includes three possible kinds of relationships. For example, “A and/or B” may represent three possible cases including “An existing alone”, “A and B existing simultaneously”, and “B existing alone”. Further, in this document, the character “/” generally indicates an “or” relationship between the associated terms before and after it.

In embodiments of the present application, the term “connected” may mean that two components are directly connected, or may mean that two components are connected via one or more other components.

It will be apparent to those skilled in the art that various modifications and variations can be made in the present application without departing from the gist or scope of the present application. Therefore, the present application is intended to cover modifications and variations of the present application that fall within the scope of the corresponding claims (claimed technical solutions) and their equivalents. It should be noted that, the embodiments according to the present application may be combined with each other as long as there is no contradiction.

Before describing the technical solutions according to the embodiments of the present application, the present application first specifically describes the problems existing in the related art to facilitate understanding of the embodiments of the present application.

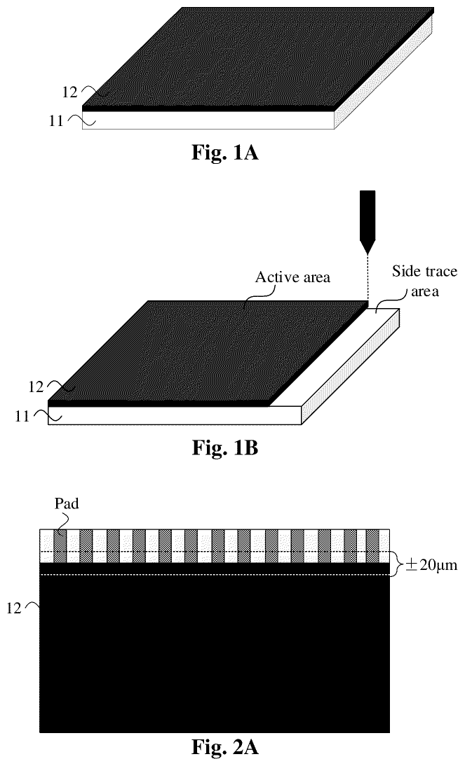

During a manufacturing process in the related art, after a thin film process on a display surface is completed, a driving circuit process is carried out on a back surface, followed by a side trace process to connect the driving circuit and a circuit on the display surface. For example, before a connecting trace is formed on a side wall of an array substrate of a display panel, as shown in FIG. 1A, a film layer is attached to the display surface of an array substrate 11 as a protective layer 12, and then, as shown in FIG. 1B, the protective layer 12 at a boundary is cut to expose a connecting pad (not shown in the figure) of the circuit of the display surface, and next, the side trace process is performed to connect the driving circuit and the circuit on the display surface. At last, the protective layer is removed. In FIG. 1B, the area where part of the protective layer 12 is cut off is a side trace area. That is, during the side trace process to connect the driving circuit and the circuit on the display surface, a connecting trace is formed in the side trace area and the side wall of the array substrate. A boundary of the side trace area is a side boundary, or referred to as a bezel boundary. As shown in FIG. 1B, the boundary is a boundary of the side trace area close to the active area.

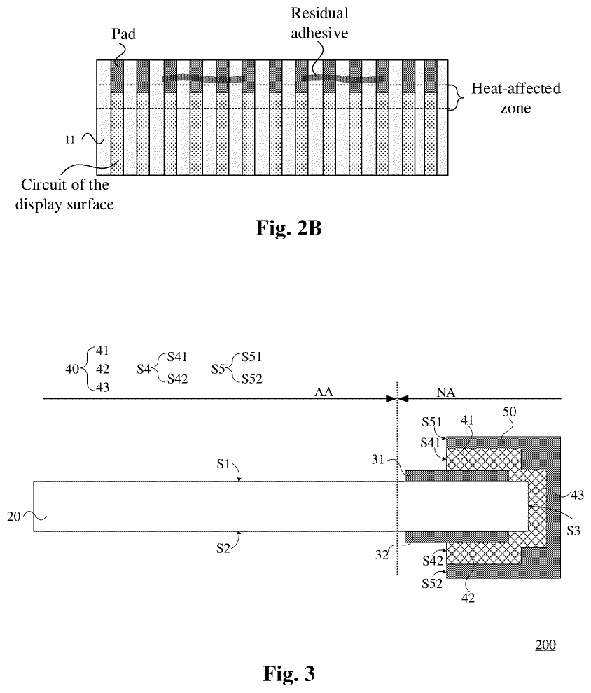

The inventors have found that, during the process of removing the protective layer 12 of the boundary, it is necessary to use a laser film cutting equipment for cutting, but the error of the laser film cutting equipment is relatively large. As shown in FIG. 2A, the laser film cutting equipment may cause an error of ±20 μm, which may cause a problem of bezel size increasing.

Further, as shown in FIG. 2B, if laser is used for cutting the film material of the protective layer 12, after the film material is removed, residual adhesive is likely to exist on pads in the active area and the boundary. In addition, there is a cutting heat-affected zone in the film material after laser cutting process, which affects characteristics of circuits. The residual adhesive and the heat-affected zone in FIG. 2B are only schematic and are not used for limiting the specific position and shape of the residual adhesive and the heat-affected zone.

In view of the above research and findings of the inventors, embodiments of the present application provide a display panel and a method for manufacturing the same, and a tiled screen device. The embodiments of the present application will be clearly and completely described hereinafter with reference to the drawings in the embodiments of the present application.

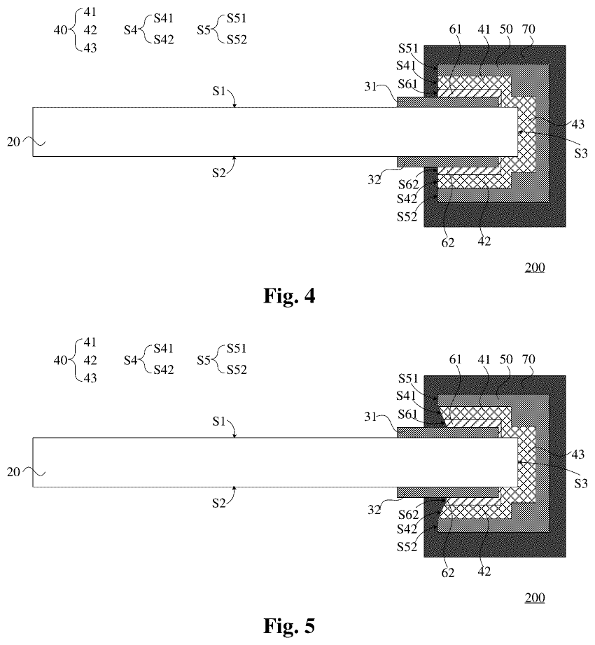

FIG. 3 shows a structural side view of a display panel provided in embodiments of the present application. As shown in FIG. 3, a display panel 200 provided in the embodiments of the present application may include an array substrate 20, a first pad 31, a second pad 32, a connecting trace 40, and a side boundary definition layer 50.

The array substrate 20 includes a first surface S1 and a second surface S2 opposite to each other, and a first side surface S3 connected to the first surface S1 and the second surface S2. One of the first surface S1 and the second surface S2 is the surface of the array substrate 20 close to the light-emission surface of the display panel, and the other one is a back surface of the array substrate 20. For example, the first surface S1 is the surface of the array substrate 20 close to the light-emission surface of the display panel, and the first surface S1 may be provided with pixel driving circuits and trace structures, such as pixel driving circuits formed by thin film transistors and capacitors, and driving signal lines. The second surface S2 is the back surface of the array substrate 20, and the second surface S2 may be provided with driving circuits for providing driving signals to the circuits on the first surface S1.

The first pad 31 is located on the first surface S1. The first pad 31 may be connected to a pixel driving circuit on the first surface S1. The second pad 32 is located on the second surface S2. The second pad 32 is connected to a driving circuit on the second surface S2.

The connecting trace 40 is connected between the first pad 31 and the second pad 32, and part of the connecting trace 40 is located on the first side surface S3. The connecting trace 40 extends along the edge region of the first surface S1, the edge region of the second surface S2, and the first side surface S3 to achieve the connection between the first pad 31 on the first surface S1 and the second pad 32 on the second surface S2.

For example, the connecting trace 40 may include a first terminal portion 41, a second terminal portion 42, and a connecting portion 43 connected between the first terminal portion 41 and the second terminal portion 42. The first terminal portion 41 of the connecting trace 40 may overlap the first pad 31, and the second terminal portion 42 of the connecting trace 40 may overlap the second pad 32. The terminal of the first pad 31 away from the first side surface S3 may be exposed beyond the connecting trace 40, that is, the terminal of the first pad 31 away from the first side surface S3 may not be covered by the connecting trace 40, thereby facilitating the connection between the first pad 31 and the pixel driving circuits or other circuits on the first surface S1. Similarly, the terminal of the second pad 32 away from the first side surface S3 may be exposed beyond the connecting trace 40, that is, the terminal of the second pad 32 away from the first side surface S3 may not be covered by the connecting trace 40, thereby facilitating the connection between the second pad 32 and the driving circuits on the second surface S2.

There may be a plurality of first pads 31, and the plurality of first pads 31 are independent of each other. There may also be a plurality of second pads 32, and the plurality of second pads 32 are independent of each other. There may be a plurality of connecting traces 40, and the plurality of connecting traces 40 are independent of each other. The connecting trace 40 may be connected between the corresponding first pad 31 and the corresponding second pad 32.

The side boundary definition layer 50 is located on an edge of the array substrate 20 and located on the side of the connecting trace 40 away from the array substrate 20. It may be understood that, the side boundary definition layer 50 may extend along the edge region of the first surface S1, the edge region of the second surface S2, and the first side surface S3. Since the side boundary definition layer 50 is located only on the side of the connecting trace 40 away from the array substrate 20, at least a second side surface S4 of the connecting trace 40 is exposed beyond the side boundary definition layer 50, that is, the second side surface S4 of the connecting trace 40 is not covered by the side boundary definition layer 50. A side surface of a terminal portion of the connecting trace 40 includes the second side surface S4, and the terminal portion of the connecting trace 40 overlaps the first pad 31 or the second pad 32. The second side surface S4 is opposite to the first side surface S3. The second side surface S4 intersects the first surface S1 and the second surface S2.

Specifically, the second side surface S4 of the connecting trace 40 may include a first sub-side surface S41 and a second sub-side surface S42, the first sub-side surface S41 of the connecting trace 40 is a side surface of the first terminal portion 41 of the connecting trace 40, the second sub-side surface S42 of the connecting trace 40 is a side surface of the second terminal portion 42 of the connecting trace 40, and the sub-side surfaces S41 and S42 of the connecting trace 40 are exposed beyond the side boundary definition layer 50.

Further, a side surface of a terminal portion of the side boundary definition layer 50 include a third side surface S5 opposite to the first side surface S3. The third side surface S5 intersects the first surface S1 and the second surface S2. The terminal portion of the side boundary definition layer 50 overlaps the terminal portion of the connecting trace 40.

Specifically, the third side surface S5 may include a third sub-side surface S51 adjacent to the first sub-side surface S41 and a fourth sub-side surface S52 adjacent to the second sub-side surface S42.

It may be understood that, the third side surface S5 of the side boundary definition layer 50 is the edge of the side boundary definition layer 50, and the third side surface S5 of the side boundary definition layer 50 may also be referred to as a side boundary of the side boundary definition layer 50. It may be understood that, the third side surface S5 of the side boundary definition layer 50 is the side surface thereof close to an active area AA. The first pads 31, the second pads 32, the connecting traces 40, and the side boundary definition layer 50 may be located in a non-active area NA of the display panel.

In the display panel according to the embodiments of the present application, since the side boundary definition layer 50 is provided, the edges (for example, sub-side surfaces S51 and S52) of the side boundary definition layer 50 may serve as the boundary in the subsequent processes. For example, if the connecting trace 40 has a portion extending beyond the edge of the side boundary definition layer 50, the connecting trace 40 extending beyond the edge of the side boundary definition layer 50 may be removed taking the edge of the side boundary definition layer 50 as the boundary to ensure that the connecting trace 40 is located within the area defined by the side boundary definition layer 50, thereby facilitating achieving narrow bezel. In addition, since the side boundary definition layer 50 is located on the edge of the array substrate, the side edge boundary may no longer be defined by pasting a film on a whole surface first and then cutting the film material on the edge, thus avoiding the influence of residual adhesive. Moreover, it can avoid using laser film cutting equipment with relatively large errors to cut the film material. For example, the side boundary definition layer may be directly formed by a photolithography or a printing process, which may reduce the error, and facilitate achieving narrow bezel.

As described above, the plurality of first pads 31 are independent of each other, the plurality of second pads 32 are independent of each other, and the plurality of connecting traces 40 are independent of each other. It may be understood that, the material of the side boundary definition layer 50 is an insulating material. For example, the material of the side boundary definition layer 50 may include adhesive or ink.

In some embodiments, still referring to FIG. 3, a maximum distance between the second side surface S4 and the first side surface S3 is less than or equal to a minimum distance between the third side surface S5 and the first side surface S3.

As described above, the second side surface S4 of the connecting trace 40 may include the first sub-side surface S41 and the second sub-side surface S42, and the third side surface S5 of the side boundary definition layer 50 may include the third sub-side surface S51 adjacent to the first sub-side surface S41 and the fourth sub-side surface S52 adjacent to the second sub-side surface S42.

Specifically, a maximum distance between the first sub-side surface S41 and the first side surface S3 is less than or equal to a minimum distance between the third sub-side surface S51 and the first side surface S3, and a maximum distance between the second sub-side surface S42 and the first side surface S3 is less than or equal to a minimum distance between the fourth sub-side surface S52 and the first side surface S3.

In embodiments of the present application, the third side surface S5 of the side boundary definition layer 50 may be farther from the first side surface S3 than the second side surface S4 of the connecting trace 40, whereby it may further ensure that the connecting trace 40 is located within the area defined by the side boundary definition layer 50, which may better facilitate achieving narrow bezel.

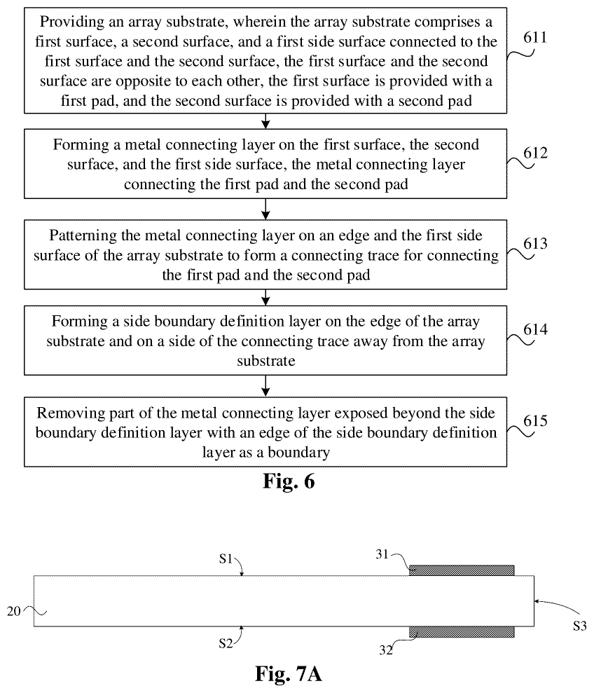

In some embodiments, as shown in FIG. 4, the display panel 200 may further include a first conductive layer 61 which is located on the first surface S1, and the first terminal portion 41 of the connecting trace 40 is connected to the first pad 31 via the first conductive layer 61.

Additionally or alternatively, the display panel 200 may further include a second conductive layer 62 which is located on the second surface S2, and the second terminal portion 42 of the connecting trace 40 is connected to the second pad 32 via the second conductive layer 62.

In embodiments of the present application, the first conductive layer 61 and/or the second conductive layer 62 may serve as a protective layer of the pads, and may prevent damages such as corrosion to the pads during the manufacturing process of the connecting trace 40.

In some embodiments, a side surface of a terminal portion of the side boundary definition layer 50 comprise a third side surface S5, a side surface of a terminal portion of the first conductive layer 61 comprises a fourth side surface S61, a side surface of a terminal portion of the second conductive layer 62 comprises a fifth side surface S62, the fourth side surface S61 is adjacent to the third side surface S5 and opposite to the first side surface S3, and the fifth side surface S62 is adjacent to the third side surface S5 and opposite to the first side surface S3. Specifically, the third side surface S5 may include a third sub-side surface S51 adjacent to the fourth side surface S61 and a fourth sub-side surface S52 adjacent to the fifth side surface S62.

A maximum distance between the fourth side surface S61 and the first side surface S3 is less than or equal to a minimum distance between the third side surface S5 and the first side surface S3. Additionally or alternatively, a maximum distance between the fifth side surface S62 and the first side surface S3 is less than or equal to a minimum distance between the third side surface S5 and the first side surface S3.

In embodiments of the present application, the third side surface S5 of the side boundary definition layer 50 is farther from the first side surface S3 than the side surface of the first conductive layer 61 and/or the second conductive layer 62, whereby it may ensure that the first conductive layer 61 and/or the second conductive layer 62 are located within the area defined by the side boundary definition layer 50, which may better facilitate achieving narrow bezel.

The fourth side surface S61 of the first conductive layer 61 is exposed beyond the side boundary definition layer 50, that is, the fourth side surface S61 of the first conductive layer 61 is not covered by the side boundary definition layer 50. The fifth side surface S62 of the second conductive layer 62 is exposed beyond the side boundary definition layer 50, that is, the fifth side surface S62 of the second conductive layer 62 is not covered by the side boundary definition layer 50.

As an example, as shown in FIG. 4, the third sub-side surface S51 may be perpendicular to the first surface S1, and the fourth sub-side surface S52 may be perpendicular to the second surface S2. The first sub-side surface S41 may be perpendicular to the first surface S1, and the second sub-side surface S42 may be perpendicular to the second surface S2. The fourth side surface S61 may be perpendicular to the first surface S1, and the fifth side surface S62 may be perpendicular to the second surface S2.

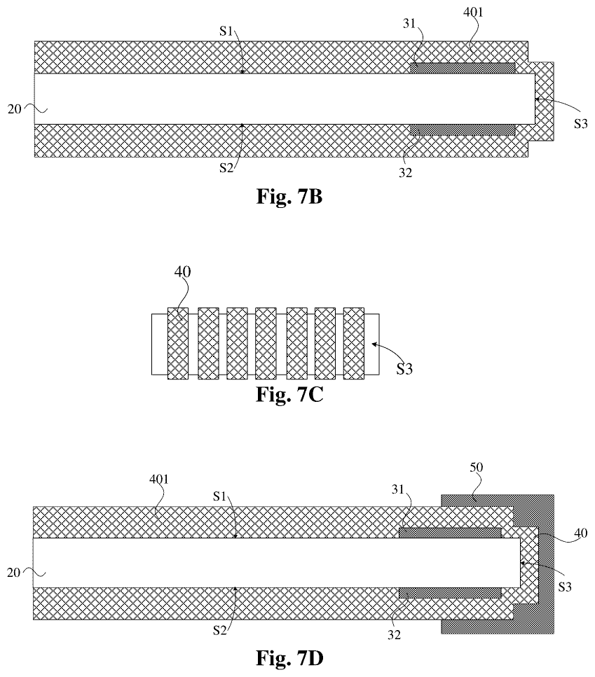

As another example, as shown in FIG. 5, the third sub-side surface S51 may be perpendicular to the first surface S1, and the fourth sub-side surface S52 may be perpendicular to the second surface S2. An included angle between the first sub-side surface S41 and the first surface S1 may be an acute angle, and an included angle between the second sub-side surface S42 and the second surface S2 may be an acute angle. An included angle between the fourth side surface S61 and the first surface S1 may be an acute angle, and an included angle between the fifth side surface S62 and the second surface S2 may be an acute angle.

In some embodiments, a wet etching process may be used for removing part of the connecting trace 40, the first conductive layer 61, and the second conductive layer 62 that are exposed beyond the area defined by the side boundary definition layer 50 to form the structures as shown in FIG. 4 or FIG. 5.

For example, the connecting trace 40 may be etchable by a chemical solution with a first acidity, and the first conductive layer 61 and/or the second conductive layer 62 may be etchable by a chemical solution with a second acidity. For example, the second acidity may be less than the first acidity.

The first conductive layer 61 and the second conductive layer 62 are closer to the pads than the connecting trace 40, and when the second acidity is less than the first acidity, it may prevent damages such as corrosion to the pads during the manufacturing process of the connecting trace 40 and the first conductive layer 61 and/or the second conductive layer 62.

Exemplarily, the material of the first conductive layer 61 and/or the second conductive layer 62 may include indium tin oxide (ITO). Additionally or alternatively, the material of the connecting trace may include titanium copper (TiCu).

As described above, the sub-side surfaces S41 and S42 of the connecting trace 40 are exposed beyond the side boundary definition layer 50, the fourth side surface S61 of the first conductive layer 61 is exposed beyond the side boundary definition layer 50, and the fifth side surface S62 of the second conductive layer 62 is exposed beyond the side boundary definition layer 50. If these conductive structures in the overlapping area with the pads are exposed to air, it is prone to water-oxygen corrosion.

In view of the above problems, in some embodiments, as shown in FIG. 4 or FIG. 5, the display panel 200 may further include an encapsulation layer 70. The encapsulation layer 70 is located on the edge of the array substrate 20 and covers the side boundary definition layer 50 and the connecting traces 40. Further, the encapsulation layer 70 may cover the first conductive layer 61 and the second conductive layer 62.

In this manner, the connecting traces 40, the first conductive layer 61, and the second conductive layer 62 may be prevented from being exposed to air under the wrapping effect of the encapsulation layer 70, thereby reducing the possibility of water-oxygen corrosion of these conductive structures.

Exemplarily, the material of the encapsulation layer 70 may include organic ink or an adhesive material, and the encapsulation layer 70 may be directly formed by printing, inkjet printing, or coating.

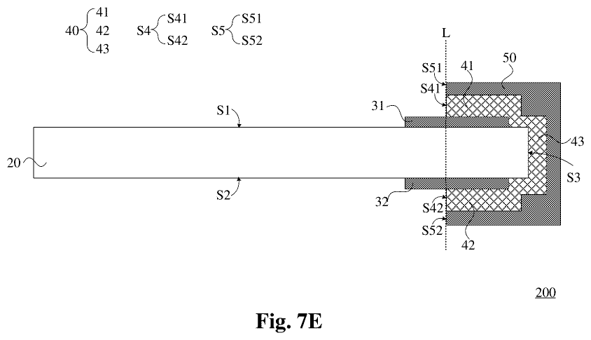

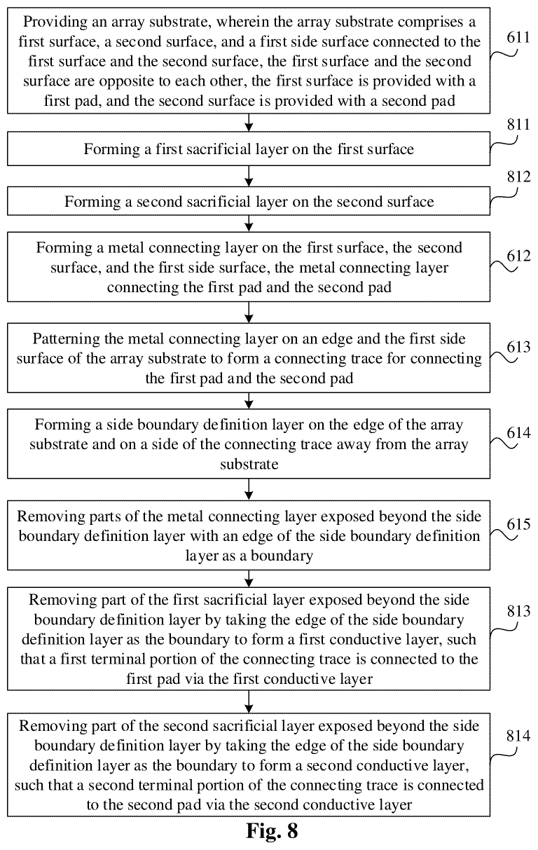

Based on the same inventive concept, embodiments of the present application further provide a method for manufacturing a display panel. As shown in FIG. 6, the method for manufacturing a display panel according to embodiments of the present application includes steps 611 to 615. FIGS. 7A to 7E show schematic views of a process for manufacturing a display panel provided in embodiments of the present application. Steps 611 to 615 will be described with reference to FIGS. 6 and 7A to 7E.

In step 611, as shown in FIG. 7A, an array substrate 20 is provided, and the array substrate 20 includes a first surface S1 and a second surface S2 opposite to each other, and a first side surface S3 connected to the first surface S1 and the second surface S2. The first surface S1 is provided with the first pad 31, and the second surface S2 is provided with the second pad 32.

In step 612, as shown in FIG. 7B, a metal connecting layer 401 is formed on the first surface S1, the second surface S2, and the first side surface S3, and the metal connecting layer 401 connects the first pad 31 and the second pad 32. Exemplarily, a TiCu film layer may be coated on the first surface S1, the second surface S2, and the first side surface S3 simultaneously to form the metal connecting layer 401. The metal connecting layer 401 may completely wrap the first pad 31 and the second pad 32. The metal connecting layer 401 is a continuous film layer.

In step 613, as shown in FIG. 7C, the metal connecting layer 401 on the edge and the first side surface S3 of the array substrate 20 is patterned to form a connecting trace 40 for connecting the first pad 31 and the second pad 32. In this manner, the different connecting traces 40 are spaced apart from each other, the different first pads 31 are spaced apart from each other, and the different second pads 32 are spaced apart from each other.

In step 614, as shown in FIG. 7D, a side boundary definition layer 50 is formed on the edge of the array substrate 20 and on the side of the connecting trace 40 away from the array substrate 20. Exemplarily, a protective film is formed using an adhesive material or ink and by a coating, transferring, or printing process to form the side boundary definition layer 50.

It may be understood that, the metal connecting layer 401 has portions that are exposed beyond the side boundary definition layer 50.

In step 615, as shown in FIG. 7E, the exposed portions of the metal connecting layer 401 beyond the side boundary definition layer 50 are removed with an edge L of the side boundary definition layer 50 as a boundary, thereby forming a display panel.

Exemplarily, the exposed portions of the metal connecting layer 401 beyond the side boundary definition layer 50 on the first surface S1 and the second surface S2 are removed by wet etching, such that each of the connecting traces 40 is independently connected to the corresponding pad.

A structure of the finally obtained display panel as shown in FIG. 7E is the same as the structure of the display panel as shown in FIG. 3, and the characteristics of the first pad 31, the second pad 32, the connecting trace 40, and the side boundary definition layer 50 are as described above, and will not be repeated here.

In the method for manufacturing a display panel according to embodiments of the present application, part of the metal connecting layer 401 exposed beyond the side boundary definition layer 50 are removed taking the edge of the side boundary definition layer 50 as the boundary to ensure that the connecting trace 40 is located within the area defined by the side boundary definition layer 50, thereby facilitating achieving narrow bezel. In addition, since the side boundary definition layer 50 is located on the edge of the array substrate, the side edge boundary may no longer be defined by pasting a film on a whole surface first and then cutting the film material on the edge, thus avoiding the influence of residual adhesive. Moreover, it can avoid using laser film cutting equipment with large errors to cut the film material. For example, the side boundary definition layer may be directly formed by a photolithography or a printing process, which may reduce the error, and facilitate achieving narrow bezel.

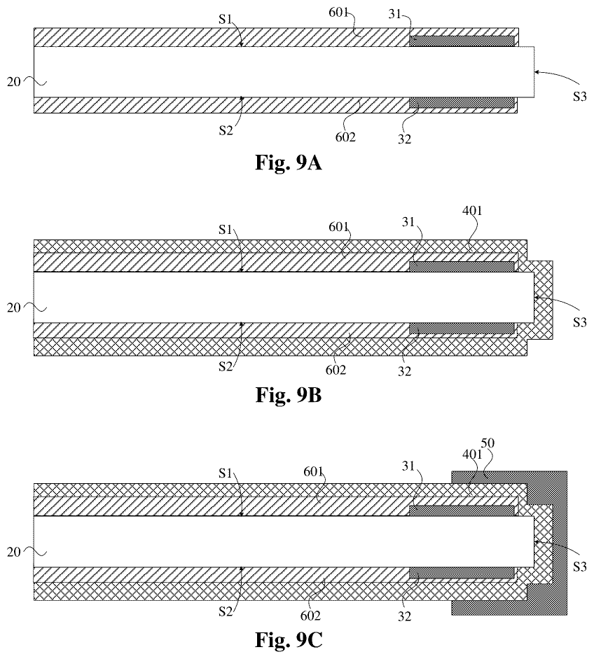

In some embodiments, as shown in FIG. 8, before step 612 and after step 611, the method for manufacturing a display panel according to embodiments of the present application may further include steps 811 and/or 812; and correspondingly, after step 615, the method for manufacturing a display panel according to embodiments of the present application may further include steps 813 and/or 814.

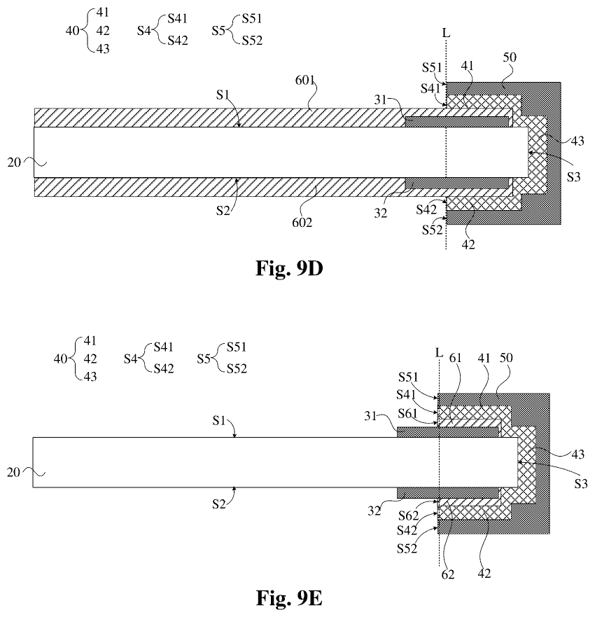

In step 811, as shown in FIG. 9A, a first sacrificial layer 601 is formed on the first surface S1. In step 812, and a second sacrificial layer 602 is formed on the second surface S2.

Exemplarily, the first sacrificial layer 601 and/or the second sacrificial layer 602 may be patterned by an exposure etching process, and the first sacrificial layer 601 and/or the second sacrificial layer 602 may be used as a protective layer to protect the structures of the first surface and the second surface of the array substrate. The first sacrificial layer 601 may completely wrap the first pad 31, and the second sacrificial layer 602 may completely wrap the second pad 32 to prevent corrosion damage to the pads of an inner layer during the etching process. The material of the first sacrificial layer 601 and/or the second sacrificial layer 602 may include ITO.

Correspondingly, in step 612, a structure as shown in FIG. 9B is formed, and the metal connecting layer 401 covers the first sacrificial layer 601 and/or the second sacrificial layer 602.

Correspondingly, in step 613, a structure as shown in FIG. 7C may still be formed.

Correspondingly, in step 614, a structure as shown in FIG. 9C may still be formed.

Correspondingly, in step 615, a structure as shown in FIG. 9D may still be formed. It may be understood that, after the exposed portions of the metal connecting layer 401 are removed, part of the first sacrificial layer 601 and/or the second sacrificial layer 602 is exposed beyond the side boundary definition layer 50.

Correspondingly, in step 813, as shown in FIG. 9E, the exposed portion of the first sacrificial layer 601 beyond the side boundary definition layer 50 is removed taking the edge L of the side boundary definition layer 50 as the boundary to form a first conductive layer 61, such that the first terminal portion 41 of the connecting trace 40 is connected to the first pad 31 via the first conductive layer 61.

Additionally or alternatively, in step 814, as shown in FIG. 9E, the exposed portion of the second sacrificial layer 602 beyond the side boundary definition layer 50 is removed taking the edge L of the side boundary definition layer 50 as the boundary to form a second conductive layer 62, such that the second terminal portion 42 of the connecting trace 40 is connected to the second pad 32 via the second conductive layer 62.

Exemplarily, the exposed portion of the first sacrificial layer 601 and/or the second sacrificial layer 602 is removed by a wet etching process to expose portions of the first pad 31 and the second pad 32 to facilitate the connection of the first pad 31 and the second pad 32 to corresponding circuit structures in the subsequent processes.

In the method for manufacturing a display panel according to embodiments of the present application, by taking the edge of the side boundary definition layer as the boundary, it may ensure that the first conductive layer 61 and/or the second conductive layer 62 are located within the area defined by the side boundary definition layer 50, which may better facilitate achieving narrow bezel.

In some embodiments, the step of removing the exposed portions of the metal connecting layer beyond the side boundary definition layer in step 615 may specifically include removing the exposed portions of the metal connecting layer beyond the side boundary definition layer by wet etching and using a chemical solution with a first acidity.

The step of removing the exposed portion of the first sacrificial layer beyond the side boundary definition layer in step 813 may specifically include removing the exposed portion of the first sacrificial layer beyond the side boundary definition layer by wet etching and using a chemical solution with a second acidity.

Additionally or alternatively, the step of removing the exposed portion of the second sacrificial layer beyond the side boundary definition layer in step 813 may specifically include removing the exposed portion of the second sacrificial layer beyond the side boundary definition layer by wet etching and using a chemical solution with a second acidity. The first acidity may be greater than the second acidity.

The first conductive layer 61 and the second conductive layer 62 are closer to the pads than the connecting traces 40, and when the second acidity is less than the first acidity, it may prevent damages such as corrosion to the pads during the manufacturing process of the connecting trace 40 and the first conductive layer 61 and/or the second conductive layer 62.

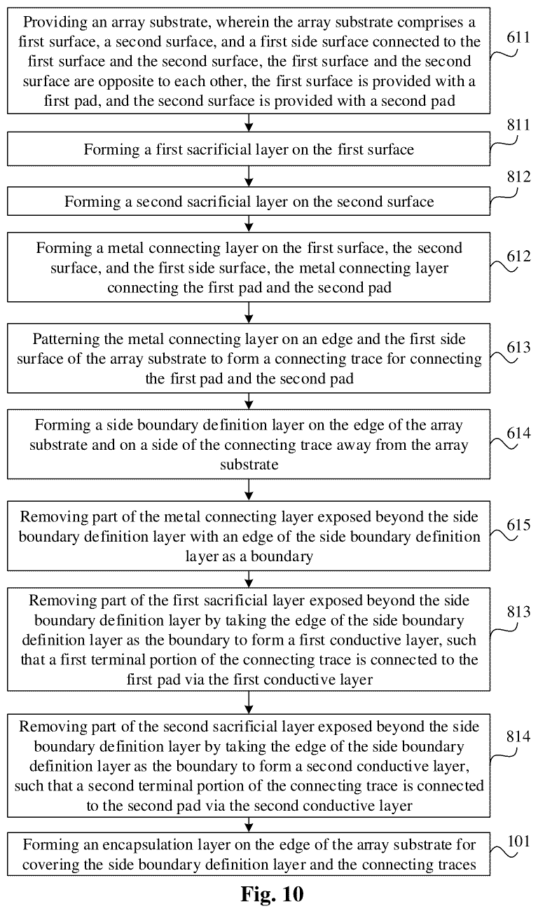

In some embodiments, at least after step 615, or in the case that steps 813 and 814 are included, after steps 813 and 814, as shown in FIG. 10, the method for manufacturing a display panel according to embodiments of the present application may further include step 101.

In step 101, as shown in FIG. 4, an encapsulation layer 70 is formed on the edge of the array substrate 20 for covering the side boundary definition layer 50 and the connecting trace 40. Further, the encapsulation layer 70 may cover the first conductive layer 61 and the second conductive layer 62.

In this manner, the connecting traces 40, the first conductive layer 61, and the second conductive layer 62 may be prevented from being exposed to air under the wrapping effect of the encapsulation layer 70, thereby reducing the possibility of water-oxygen corrosion of these conductive structures.

Exemplarily, the material of the encapsulation layer 70 may include organic ink or an adhesive material, and the encapsulation layer 70 may be directly formed by printing, inkjet printing, or coating.

Based on the same inventive concept, embodiments of the present application further provide a tiled screen device including a display panel according to any one of the above embodiments of the present application. Therefore, the tiled screen device has the technical features of the display panel according to embodiments of the present application, and can achieve the beneficial effects of the display panel according to embodiments of the present application. For similarities, the above description of the display panel according to embodiments of the present application may be referred to, which will not be repeated here.

In accordance with the embodiments of the present application as described above, these embodiments do not exhaustively describe all the details, nor do they limit the application to only the specific embodiments described. Obviously, many modifications and variations are possible in light of the above description. These embodiments are specifically described in this specification to better explain principles and practical usage of the present application, so that those skilled in the art can make good use of the present application and modify and use it based on the present application. This application is to be limited only by the claims, along with their full scope and equivalents.

What is claimed is:

1. A display panel, comprising:
an array substrate, comprising a first surface, a second surface, and a first side surface connecting the first surface and the second surface, the first surface and the second surface being opposite to each other;
a first pad, located on the first surface;
a second pad, located on the second surface;
a connecting trace, connecting the first pad and the second pad, wherein the connecting trace is at least partially located on the first side surface; and
a side boundary definition layer, located on an edge of the array substrate and located on a side of the connecting trace away from the array substrate.

2. The display panel according to claim 1, wherein
a side surface of a terminal portion of the connecting trace comprises a second side surface,
a side surface of a terminal portion of the side boundary definition layer comprises a third side surface,
the second side surface and the third side surface are adjacent to each other and are opposite to the first side surface, and
a maximum distance between the second side surface and the first side surface is less than or equal to a minimum distance between the third side surface and the first side surface.

3. The display panel according to claim 1, wherein the display panel further comprises a first conductive layer located on the first surface, and a first terminal portion of the connecting trace is connected to the first pad via the first conductive layer.

4. The display panel according to claim 3, wherein the display panel further comprises a second conductive layer located on the second surface, and a second terminal portion of the connecting trace is connected to the second pad via the second conductive layer.

5. The display panel according to claim 4, wherein
a side surface of a terminal portion of the side boundary definition layer comprises a third side surface,
a side surface of a terminal portion of the first conductive layer comprises a fourth side surface,
a side surface of a terminal portion of the second conductive layer comprises a fifth side surface,
the third side surface and the fourth side surface are adjacent to each other and are opposite to the first side surface, and
the third side surface and the fifth side surface are adjacent to each other and are opposite to the first side surface.

6. The display panel according to claim 5, wherein a maximum distance between the fourth side surface and the first side surface is less than or equal to a minimum distance between the third side surface and the first side surface.

7. The display panel according to claim 5, wherein a maximum distance between the fifth side surface and the first side surface is less than or equal to a minimum distance between the third side surface and the first side surface.

8. The display panel according to claim 4, wherein the connecting trace is etchable by a chemical solution with a first acidity, and the first conductive layer and/or the second conductive layer is etchable by a chemical solution with a second acidity.

9. The display panel according to claim 3, wherein a material of the first conductive layer comprises indium tin oxide.

10. The display panel according to claim 4, wherein a material of the second conductive layer comprises indium tin oxide.

11. The display panel according to claim 1, wherein a material of the connecting trace comprises titanium copper.

12. The display panel according to claim 8, wherein the second acidity is less than the first acidity.

13. The display panel according to claim 1, wherein the display panel further comprises:
an encapsulation layer located on an edge of the array substrate and covering the side boundary definition layer and the connecting trace.

14. A method for manufacturing a display panel, comprising:
providing an array substrate, wherein the array substrate comprises a first surface, a second surface, and a first side surface connecting the first surface and the second surface, the first surface and the second surface are opposite to each other, the first surface is provided with a first pad, and the second surface is provided with a second pad;
forming a metal connecting layer on the first surface, the second surface, and the first side surface, the metal connecting layer connecting the first pad and the second pad;
patterning the metal connecting layer on an edge and the first side surface of the array substrate to form a connecting trace for connecting the first pad and the second pad;
forming a side boundary definition layer on the edge of the array substrate and on a side of the connecting trace away from the array substrate; and
removing part of the metal connecting layer exposed beyond the side boundary definition layer by taking an edge of the side boundary definition layer as a boundary.

15. The method according to claim 14, wherein before the forming a metal connecting layer on the first surface, the second surface, and the first side surface, the method further comprises:
forming a first sacrificial layer on the first surface; and
correspondingly, after the removing part of the metal connecting layer exposed beyond the side boundary definition layer, the method further comprises:
removing part of the first sacrificial layer exposed beyond the side boundary definition layer by taking the edge of the side boundary definition layer as the boundary to form a first conductive layer, such that a first terminal portion of the connecting trace is connected to the first pad via the first conductive layer.

16. The method according to claim 14, wherein before the forming a metal connecting layer on the first surface, the second surface, and the first side surface, the method further comprises:
forming a second sacrificial layer on the second surface; and
correspondingly, after the removing part of the metal connecting layer exposed beyond the side boundary definition layer, the method further comprises:
removing part of the second sacrificial layer exposed beyond the side boundary definition layer taking the edge of the side boundary definition layer as the boundary to form a second conductive layer, such that a second terminal portion of the connecting trace is connected to the second pad via the second conductive layer.

17. The method according to claim 15, wherein the removing part of the metal connecting layer exposed beyond the side boundary definition layer comprises:
removing the part of the metal connecting layer exposed beyond the side boundary definition layer by wet etching and using a chemical solution with a first acidity; and
the removing part of the first sacrificial layer exposed beyond the side boundary definition layer comprises:
removing the part of the first sacrificial layer exposed beyond the side boundary definition layer by wet etching and using a chemical solution with a second acidity.

18. The method according to claim 16, wherein the removing part of the second sacrificial layer exposed beyond the side boundary definition layer comprises:
removing the part of the second sacrificial layer exposed beyond the side boundary definition layer by wet etching and using a chemical solution with a second acidity.

19. The method according to claim 14, wherein, after the removing part of the metal connecting layer exposed beyond the side boundary definition layer, the method further comprises:
forming an encapsulation layer on the edge of the array substrate for covering the side boundary definition layer and the connecting trace.

20. A tiled screen device comprising a display panel, wherein
the display panel, comprising:
an array substrate, comprising a first surface, a second surface, and a first side surface connecting the first surface and the second surface, the first surface and the second surface being opposite to each other;
a first pad, located on the first surface;
a second pad, located on the second surface;
a connecting trace, connecting the first pad and the second pad, wherein the connecting trace is at least partially located on the first side surface; and
a side boundary definition layer, located on an edge of the array substrate and located on a side of the connecting trace away from the array substrate.
